(19) United States
(12) Patent Application Publication
(10) Pub. No.: US 2026/0173486 A1
(43) Pub. Date: Jun. 18, 2026

(54) SELECTIVE CHEMICAL ATOMIC LAYER ETCHING FOR METAL CONTAINING COMPOUNDS

(71) Applicant: TOKYO ELECTRON LIMITED, Tokyo (JP)

(72) Inventors: Ryota YONEZAWA, Albany, NY (US); Kai-Hung YU, Albany, NY (US); Tadahiro ISHIZAKA, Nirasaki City (JP); Takashi SAKUMA, Nirasaki City (JP); Hidenao SUZUKI, Albany, NY (US)

(73) Assignee: TOKYO ELECTRON LIMITED, Tokyo (JP)

(21) Appl. No.: 18/979,279

(22) Filed: Dec. 12, 2024

(51) Int. Cl. H10D 64/66; H01L 21/02; H01L 21/768; H10D 64/68

(52) U.S. Cl. CPC H10D 64/669; H10D 64/693; H10P 14/6528; H10W 20/054

(57) ABSTRACT

A method includes providing a substrate comprising a silicon-containing source/drain region recessed within an interlayer dielectric opening which exposes the source/drain region. A first metal is deposited on the substrate such that the first metal reacts with the source/drain region to form a metal contact film on a surface of the source/drain region and forms a metal-containing compound comprising the first metal on a surface of the interlayer dielectric. The substrate is exposed to an atomic layer etching process to remove at least part of the metal-containing compound. The interlayer dielectric opening is filled with a second metal.

### TECHNICAL FIELD

The present invention relates generally to the field of semiconductor device fabrication, and more particularly, to selective etching of metal-containing compounds.

### BACKGROUND

Advancement in semiconductor technologies relies on continued improvement in manufacturing fabrication technology. Innovation in semiconductor technologies has resulted in the introduction of new types of structures such as FinFET devices and stacked structures (e.g., 3D NAND devices). However, these new structures introduce a need for new fabrication schemes to overcome, what would otherwise be, debilitating manufacturing challenges. For instance, a metal contact film may be deposited on source/drain structures recessed within openings in a dielectric material in order to minimize resistance and improve current flow from the source/drain to metal contact material filled in the opening. However, formation of the metal contact film can result in undesired deposition of metal-containing compounds on adjacent structures such as sidewalls of the contact opening. Existing techniques for etching such unwanted deposits can in turn lead to undesired removal of other materials from the structure. These issues often cause uncontrolled variations in device electrical performance, as well as yield loss.

### SUMMARY

The present disclosure relates to a semiconductor device, and a method of manufacturing a semiconductor device.

An aspect (1) provides a method, comprising: providing a substrate comprising a silicon-containing source/drain region recessed within an interlayer dielectric opening which exposes the source/drain region. A first metal is deposited on the substrate such that the first metal reacts with the source/drain region to form a metal contact film on a surface of the source/drain region and forms a metal-containing compound comprising the first metal on a surface of the interlayer dielectric. The substrate is exposed to an atomic layer etching process to remove at least part of the metal-containing compound. The interlayer dielectric opening is filled with a second metal.

An aspect (2) includes the method of aspect (1), wherein the depositing a first metal on the substrate comprises using a plasma deposition process to selectively deposit the first metal on the source/drain region relative to the interlayer dielectric.

An aspect (3) includes the method of aspect (1), wherein the silicon-containing source/drain region comprises at least one of SiGe and SiP.

An aspect (4) includes the method of aspect (1), wherein the interlayer dielectric region comprises at least one of SiN and SiO2.

An aspect (5) includes the method of aspect (1), wherein the first metal comprises at least one of Ti and W, and the metal contact film comprises at least one of TiSiₓ or a WSiₓ.

An aspect (6) includes the method of aspect (1), wherein the metal-containing compound is formed on a surface of the metal contact film and on a sidewall of the interlayer dielectric opening.

An aspect (7) includes the method of aspect (1), wherein the metal-containing compound comprises a metal oxide of the first metal.

An aspect (8) includes the method of aspect (1), wherein the metal oxide is at least one of TiO₂, TiON, TiSiON, and WO.

An aspect (9) includes the method of aspect (1), wherein the exposing comprises performing an atomic layer etching process using a fluorine-based gas and a chlorine-based gas.

An aspect (10) includes the method of aspect (9), wherein the atomic layer etching process comprises exposing the substrate to a plurality of cycles of alternate exposures to a fluorine-based gas and a chlorine-based gas.

An aspect (11) includes the method of aspect (9), wherein the fluorine-based gas comprises at least one of WF₆, HF and TiF₄, and the chlorine-based gas comprises at least one of BCl₃, WCl₅ and TiCl₄.

An aspect (12) includes the method of aspect (9), further comprising removing the fluorine-based gas or chlorine-based gas between exposures.

An aspect (13) includes the method of aspect (1), wherein the atomic layer etching process selectively etches the metal-containing compound relative to the metal contact film on the source/drain region and relative to the interlayer dielectric.

An aspect (14) includes the method of aspect (1), wherein the source/drain region comprises SiGe, the first metal comprises Ti, the contact film comprises TiSiₓ, and the metal-containing compound comprises TiON.

An aspect (15) includes the method of aspect (1), further comprising performing a fluorine removal process after the atomic layer etching process and before performing the metal fill.

An aspect (16) includes the method of aspect (15), wherein the fluorine removal process comprises exposing the substrate to a silicon precursor gas.

An aspect (17) includes the method of aspect (15), wherein the fluorine removal process comprises exposing the substrate to an H₂ plasma.

An aspect (18) includes the method of aspect (1), wherein the second metal is Ru.

Another aspect (19) provides a semiconductor device, comprising: a substrate comprising a silicon-containing source/drain region recessed within an interlayer dielectric opening, and a metal contact film comprising a first metal provided on the source/drain region within the interlayer dielectric opening. A metal fill comprising a second metal provided on the metal contact film within the interlayer dielectric opening. A first interface of the metal fill with the metal contact film at a bottom of the interlayer dielectric opening is substantially free of oxygen, and a second interface of the metal fill with the interlayer dielectric at a sidewall of the interlayer dielectric opening is substantially free of metal.

An aspect (20) includes the semiconductor device of aspect (19), wherein the source/drain region comprises SiGe, the interlayer dielectric comprises SiN, the metal contact film comprises TiSiₓ, and the metal fill comprises Ru.

Note that this summary section does not specify every embodiment and/or incrementally novel aspect of the present disclosure or claimed disclosure. Instead, this summary only provides a preliminary discussion of different embodiments and corresponding points of novelty over conventional techniques. For additional details and/or possible perspectives of the present disclosure and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 schematically shows a FinFET structure in accordance with an example embodiment of the present disclosure;

FIGS. 2A, 2B, 2C, and 2D are cross sectional views of a semiconductor structure at various stages of device fabrication, in accordance with an example embodiment of the present disclosure;

FIG. 3 shows a process flow for manufacturing a semiconductor device in accordance with example embodiments of the present disclosure;

FIG. 4 shows transmission electron microscopy (TEM) cross-section images of device structures showing the effects of an ALE process in accordance with embodiment disclosed herein;

FIG. 5 shows TEM cross-section images of device structures showing the effects of an ALE process in accordance with embodiment disclosed herein;

FIG. 6 shows TEM cross-section images of device structures showing the effects of an ALE process in accordance with embodiment disclosed herein;

FIG. 7 shows TEM cross-section images of device structures showing the effects of an ALE process in accordance with embodiment disclosed herein;

FIGS. 8A and 8B are cross sectional views of a semiconductor structure at various stages of device fabrication, in accordance with an example embodiment of the present disclosure;

FIGS. 9A and 9B are graphs showing a depth profile analysis of concentration of elements in a semiconductor structure before and after etch residue treatment process in accordance with an example embodiment of the present disclosure; and

FIG. 10 is graph showing quantities of etch residue in a semiconductor structure before and after etch residue treatment process in accordance with an example embodiment of the present disclosure.

### DETAILED DESCRIPTION OF ILLUSTRATIVE EMBODIMENTS

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A “substrate,” as used herein, refers to any substrate or material surface formed on a substrate upon which film processing is performed during a fabrication process. For example, a substrate surface on which processing can be performed include material such as silicon, silicon oxide, strained silicon, bulk silicon wafer, silicon on insulator (SOI) wafer, carbon doped silicon oxides, amorphous silicon, doped silicon, silicon carbide, germanium, gallium arsenide, glass, sapphire, and any other conductive materials, depending on the application. Substrates include, without limitation, semiconductor wafers. The substrate may comprise layers of semiconductors including, but not limited to, epitaxial silicon, silicon germanium, silicon carbon, gallium nitride, indium phosphide, gallium phosphide, indium antimonide, and the like. Substrates may be exposed to a pretreatment process to polish, etch, reduce, oxidize, hydroxylate, anneal, UV cure, e-beam, and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been removed from a substrate surface, the exposed surface of the newly exposed film, layer, or substrate surface.

As noted in the Background section, techniques for etching unwanted metal-containing deposits can lead to removal of desired materials which often causes uncontrolled variations in device electrical performance, as well as yield loss. For example, direct plasma exposure with conventional etchant gases to remove metal-containing compounds from the side walls of interlayer dielectric contact openings can result in removal of the source/drain metal contact film itself and/or removal of the interlayer dielectric material causing unacceptable profile damage. Further, these etch processes can leave fluorine residue which may cause corrosion and other undesirable affects to the device structure.

Techniques disclosed herein provide for selective removal of metal-containing compounds from the sidewall of source/drain contact openings while minimizing removal of source/drain contact films and interlayer dielectric materials. Such techniques can maximize the amount of metal filling at source/drain contacts. Further, techniques herein provide for mitigating the effects of residual etchant chemistry resulting from efforts to remove metal-containing compounds from source/drain contact openings.

The present invention will be described in terms of various illustrative example processes for fabricating FET semiconductor structures on a circuit supporting substrate. These fabrication processes may be used to fabricate planar FET semiconductor devices, FinFET semiconductor devices, gate-all-around (GAA) semiconductor devices and other transistor architectures on a circuit supporting substrate.

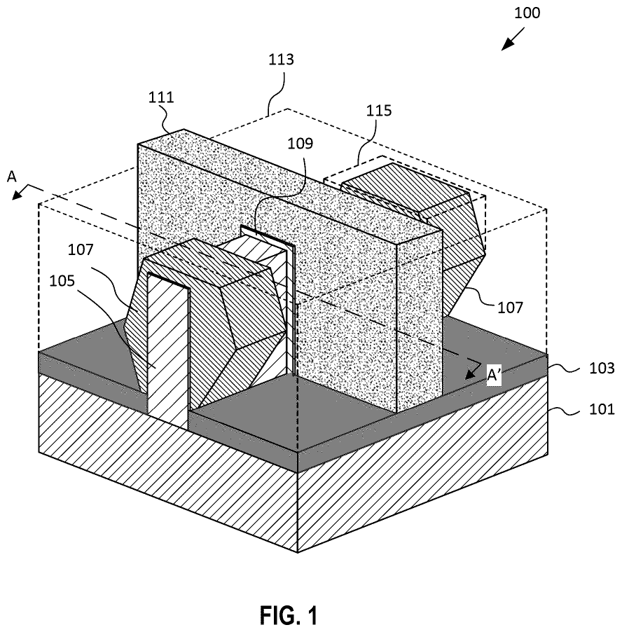

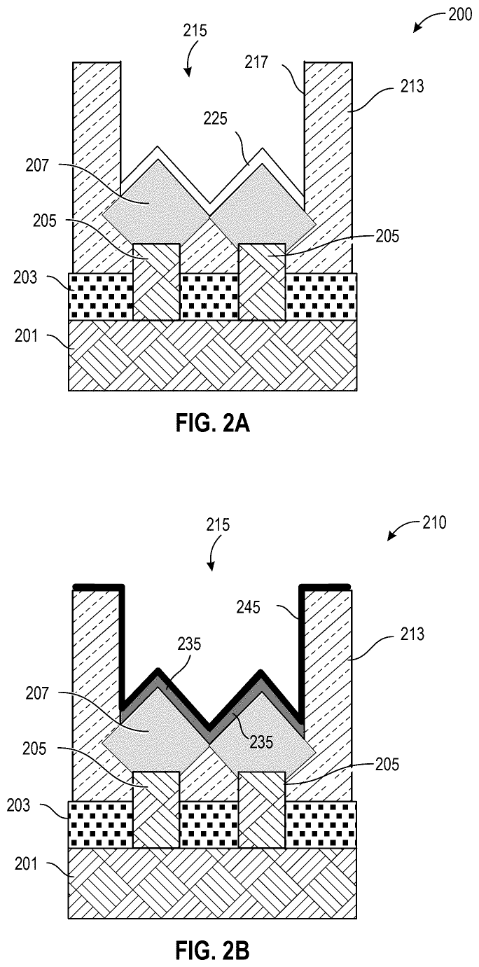

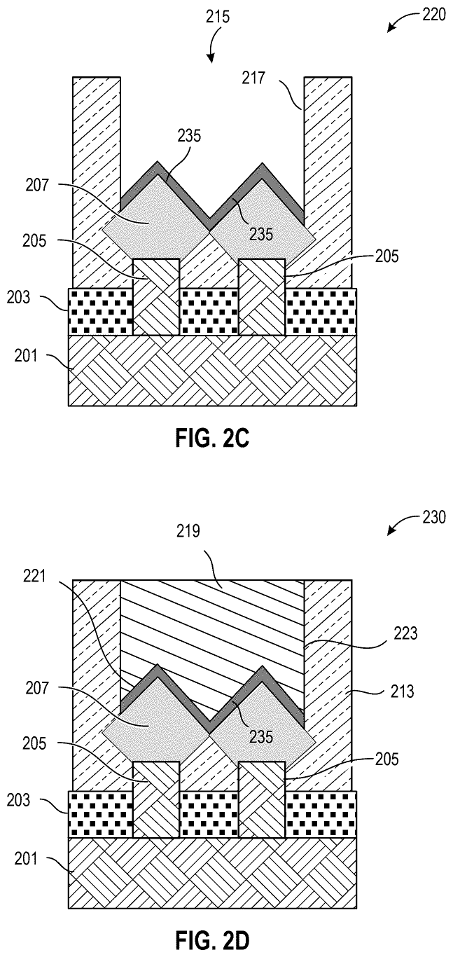

FIG. 1 schematically shows a FinFET device structure in accordance with an example embodiment of the present disclosure. The structure 100 is formed on a substrate 101 having isolation dielectric 103 thereon. The structure 100 includes a fin 105, epitaxial Si source/drain contacts 107 on the fin 105, a gate dielectric 109 over the fin 105, and a metal gate 111 over the gate dielectric 109. Interlayer dielectric 113 is shown as transparent to reveal details of the structure 100. An example contact opening 115 in the interlayer dielectric is shown for one of the source/drain contacts 107. A fin cut A-A′ is indicated across the epitaxial Si source/drain contacts 107 and the fin 105. Similar fin cuts of a FinFET are shown in FIGS. 2A-2D discussed below.

Techniques disclosed herein provide processing of the source/drain contacts 107 and interlayer dielectric 113 through contact opening 115 to improve contact resistance while minimizing feature profile damage. It is to be understood that techniques disclosed herein are not limited to FinFET structures. For example, in some embodiments, the fin 105 of FIG. 1 may be divided into vertically aligned nanosheets, nanowires, nanobars, etc. for implementation of GAA architectures.

FIGS. 2A-2D illustrate partial cross sectional fin cuts of a semiconductor device during fabrication in accordance with an example embodiment of the present disclosure. At this stage of processing, the semiconductor device 100 has already gone through a substantial part of the front-end-of-the-line (FEOL) fabrication. For example, as illustrated in FIG. 2A, FinFET structure 200 is formed on a substrate 201 having shallow isolation regions 203 thereon. The structure 200 includes adjacent fins 205, having source/drain contact 207 formed thereon. Interlayer dielectric 213 is formed around the contact structures and a source/drain contact opening 215 having sidewall 217 is formed in the interlayer dielectric to expose the source/drain contact 207 for processing.

In various embodiments, the substrate 201 may comprise silicon, silicon germanium, silicon carbide, and compound semiconductors such as gallium nitride, gallium arsenide, indium arsenide, indium phosphide, and others. The substrate 201 may comprise a semiconductor wafer that may include a semiconductor epitaxial layer including hetero epitaxial layers. For example, in one or more embodiments, one or more hetero epitaxial layers comprising a compound semiconductor may be formed over a semiconductor substrate. In various embodiments, a portion or an entirety of the substrate 201 may be amorphous, polycrystalline, or single-crystalline. In various embodiments, the substrate 201 may be doped, undoped, or contain both doped and undoped regions.

The plurality of fins 205 may be formed by epitaxial growth from the substrate 201 or alternatively using an etch back process leaving the plurality of fins 205. The plurality of fins 205 may be isolated from each other by shallow isolation regions 203. Accordingly, the shallow isolation regions 203 and the plurality of fins 205 may form an alternating pattern. In one embodiment, the shallow isolation regions 203 may be formed by depositing an oxide fill material after patterning the plurality of fins 205, which is then planarized, for example, using a chemical mechanical planarization process. After a planarization, the shallow isolation regions 203 may be recessed so as to raise the plurality of fins 205.

Source/drain contacts 207 are formed from epitaxial regions grown over respective portions of the plurality of fins 205. In the example embodiment of FIG. 2A, source/drain contact 207 is formed by epitaxial growth of silicon containing material on the respective fins 205 until the adjacently grown structures merge into a single source/drain contact 207 as shown. This is commonly referred to as a multi-gate FET (MuGFET) architecture. As depicted, the upper surface of the raised source/drain contact 207 may form a faceted surface due to the growth pattern of the corresponding epitaxial material. In some embodiments, the source/drain contact contain Si, Ge, or both Si and Ge.

In one or more embodiments, the source/drain contact 207 may be formed in a single epitaxial growth process. In other embodiments, the growth of the epitaxial regions may consist of a multi-stage process. For example, it can begin with growing an initial epitaxial layer with a first doping on the plurality of fins 205 to a pre-determined thickness followed by the growth of a second layer with a second doping. For example, the second doping may be higher than the first doping. Similarly, the different layer may have different compositions of e.g., germanium or other compounds. The epitaxial growth process may use any type of epitaxial process including molecular beam epitaxy (MBE), or various types of chemical vapor deposition (CVD).

In one or more embodiments, the source/drain contact 207 may be epitaxially grown to introduce strain into the plurality of fins 205, for example, due to lattice mismatch. In one or more embodiments, the source/drain regions may be formed by doping the regions of the fins and the epitaxial regions, for example, with an implantation/anneal process.

Where a native oxide 225 is present on the source/drain contact 207 as shown in FIG. 2A, an oxide removal process is performed to remove the native oxide prior to forming a metal contact connection to the source/drain contact 207.

FIG. 2B shows a structure 210 after native oxide removal and deposition of a metal contact film 235 on the source/drain contact 207. In one example embodiment, the metal contact material is Titanium (Ti) which forms TiSiₓ with Si from the underlying source/drain contact 207. In some embodiments, the metal contact film 235 is formed by selective deposition in an effort to form the metal contact film only on a surface of the source/drain contact 207. The present inventors recognized, however, that metal deposition processes often do not provide a level of selectivity to ensure that the metal contact film 235 is deposited only on the source/drain contact 207. For example, the inventors recognized that advanced hardware for performing plasma enhanced chemical vapor deposition (PECVD) to selectivity deposit Ti on Si relative to SiO2 can achieve an Si:SiO2 selectivity of approximately 8:1. Thus, a thin layer of Ti containing material such as TiON is expected to be formed on the interlayer dielectric 213 including inner sidewalls 217 of the contact opening 215. In the example of FIG. 2B, selective deposition of the metal contact film 235 results in formation of a metal silicide layer 235 selectively formed on the source/drain contact 207 with an undesirable metal-containing compound layer 245 formed on the silicide 235 and on the interlayer dielectric including sidewalls 217 of the opening 215.

FIG. 2C shows a structure 220 after removal of the metal-containing compound layer 245. Embodiments of the present disclosure provide selective etching of the metal-containing compound to substantially remove the metal-containing compound layer 245 from the metal contact layer 235 (e.g., silicide) and from the interlayer dielectric 213 while minimizing removal of the silicide 235 itself and minimizing removal of the interlayer dielectric 213. In some embodiments, the selective etch is an atomic layer etch (ALE) process as described further below.

After removal of the metal-containing compound layer 245, a contact metal fill material is deposited in the contact opening 215. FIG. 2D shows a structure 230 after metal fill 219 is deposited to fill the contact opening 215. As shown, the metal fill process forms interface 221 of the metal fill material 219 with the metal contact layer 235, as well as interface 223 of the metal fill material 219 with the sidewall 217 of interlayer dielectric 213.

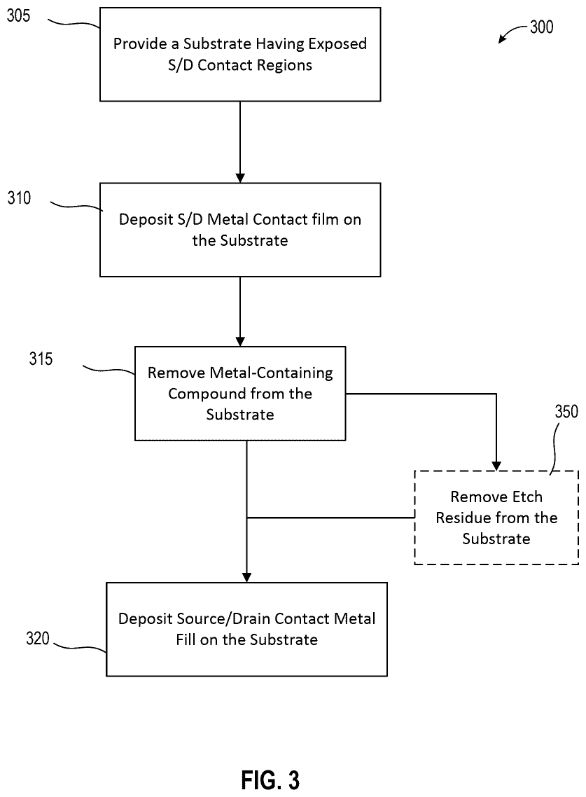

FIG. 3 shows a process flow for manufacturing a semiconductor device in accordance with embodiments of the present disclosure. The process 300 includes step 305 of providing a substrate including a silicon-containing source/drain region recessed within an interlayer dielectric opening which exposes the source/drain region. In some embodiments, the silicon-containing source/drain region can include at least one of SiGe and SiP, and the interlayer dielectric region can include at least one of SiN and SiO₂. Where the silicon-containing source/drain region includes a native oxide such as that shown in FIG. 2A, an oxide treatment can optionally be performed to remove the native oxide.

In step 310, a source/drain contact layer is formed on the source/drain contact region. In some embodiments, step 310 includes depositing a first metal on the substrate such that the first metal reacts with the source/drain material to form a metal contact film on a surface of the source/drain contact region. For example, the first metal can be at least one of Ti and W, and the metal contact film can be at least one of TiSiₓ or a WSiₓ. Step 310 also results in forming a metal-containing compound of the first metal on a surface of the interlayer dielectric. For example, an oxide of the first metal, such as TiO, TiO₂ or WO, may be formed on the interlayer dielectric including a sidewall of the interlayer dielectric opening. The metal-containing compound can also include a nitride such as with TiON and TiSiON.

In some embodiments, the first metal is deposited on the substrate using a plasma deposition process to selectively deposit the first metal on the source/drain region relative to the interlayer dielectric region. Such selective deposition is expected to also deposit the metal-containing compound on the interlayer dielectric surfaces including the sidewall of the interlayer opening. As shown in the example of FIG. 2B, the metal-containing compound 245 may be formed on a sidewall 217 of the interlayer dielectric opening 215 and also on a surface of the metal contact film 235.

In step 315, the metal-containing compound is removed from the substrate using atomic layer etching. “Atomic layer etching (ALE)” or “cyclical etching” is a variant of atomic layer deposition (ALD) wherein a surface layer is removed from a substrate. As used herein, ALE refers to the sequential exposure of two or more reactive compounds to etch a layer of material on a substrate surface. The substrate, or portion of the substrate, is exposed separately to the two or more reactive compounds which are introduced into a reaction zone of a processing chamber.

ALE is a film etching technique that consists of sequential self-limiting reactions. The first step modifies the surface by adsorption of a precursor vapor to form a thin layer. The second step is removal of at least a portion of the formed layer. Each step is self-limiting, and only a thin layer is removed by one cycle of ALE process. To achieve a desired amount of etching, steps are typically repeated and so an ALE process generally refers to the sequential cycles of such steps.

ALE may be used for etching of different materials such as Si, W, SiO₂, metal oxides (e.g., Al₂O₃, HfO₂, ZrO₂, ZnO, TiO₂, WO₃, and the like), metal nitrides (e.g., Si₃N₄, GaN, TiN, AlN, and the like), and metal fluorides (e.g., AlF₃).

In a time-domain ALE process, exposure to each reactive compound is separated by a time delay to allow each compound to adhere and/or react on the substrate surface and then be purged from the processing chamber. These reactive compounds are said to be exposed to the substrate sequentially.

In one aspect of a time-domain ALE process, a first reactive gas (i.e., a first reactant, compound A, or a fluorine-based gas) is exposed to a substrate in a process chamber followed by a first time delay. Next, a second reactive gas (i.e., a second reactant, compound B, or a chlorine-based gas) is exposed to the substrate followed by a second time delay. The reactive gases (the first reactive gas and the second reactive gas) may be pulsed into the process chamber, continuously flowed, or a mixture thereof. During each time delay, a purge gas, such as argon, and/or a vacuum is introduced into the process chamber to purge the substrate or otherwise remove any residual reactive compound or reaction by-products from the substrate and/or process chamber. Alternatively, the purge gas may flow continuously throughout the etching process so that only the purge gas flows during the time delay between exposure to the reactive gases. The reactive gases are alternatively pulsed until a desired film or film thickness is removed from the substrate surface.

The ALE process of pulsing compound A, purge gas/vacuum, compound B, and purge gas/vacuum is referred to as a cycle. A cycle can start with either compound A or compound B and continue the respective order of the cycle until a predetermined thickness is removed.

Step 315 includes exposing the substrate to an ALE process to remove at least part of the metal-containing compound. In one example, the ALE process uses a fluorine-based gas and a chlorine-based gas. The atomic layer etching process includes exposing the substrate to a plurality of cycles of alternate exposures to a fluorine-based gas and a chlorine-based gas. The fluorine-based gas can include at least one of WF₆, HF and TiF₄, for example, and the chlorine-based gas can include at least one of BCl₃, WCl₅ and TiCl₄, for example. In some embodiments, the fluorine-based gas and/or chlorine-based gas can be removed between exposures. The atomic layer etching process selectively etches the metal-containing compound relative to the contact film on the source/drain region, and also relative to the interlayer dielectric.

Once the metal-containing compound is removed, a source/drain contact metal fill can be deposited on the substrate as shown by step 320. A second metal such as Ru may be used as the contact metal fill.

The process 300 can provide for improved semiconductor devices having a silicon-containing source/drain region recessed within an interlayer dielectric opening, a metal contact film provided on the source/drain region within the interlayer dielectric opening, and a metal fill provided on the metal contact film within the interlayer dielectric opening such as that shown in the example of FIGS. 2A-2D. Where the source/drain region is SiGe, the contact film includes TiSiₓ, the metal-containing compound includes TiON, and the metal fill is Ru, a first interface 221 of the metal fill 219 with the metal contact film 235 at a bottom of the interlayer dielectric opening is substantially free of oxygen, and a second interface 223 of the metal fill 219 with the interlayer dielectric at a sidewall 217 of the interlayer dielectric opening is substantially free of metal.

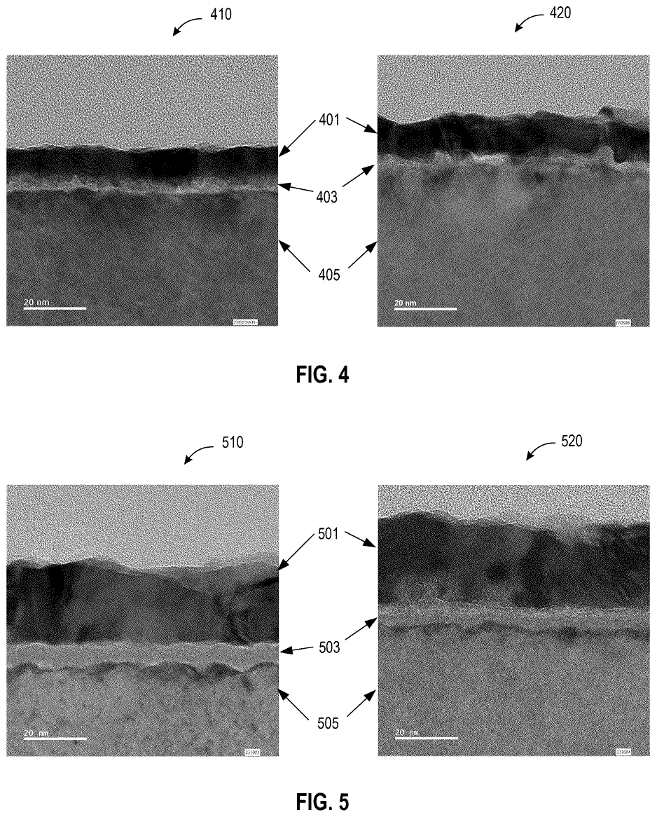

FIG. 4 shows scanning transmission electron microscopy (TEM) cross-section images of device structures showing the effects of an ALE process in accordance with embodiments disclosed herein. The image of structure 410 shows the results of a process of sequentially depositing Ti and Ru on SiN without performing selective ALE, while the image of structure 420 shows the results of the same process with selective ALE performed. The structure 410 shows a well-defined TiON layer 403 formed on the SiN base layer 405, and an Ru layer 401 formed on the TiON layer when ALE etch is not performed prior to depositing the Ru. Elemental mapping of the structure 410 by Energy-Dispersive X-ray Spectroscopy (EDX) confirmed substantial amounts of O, Ti, and N between the SiN base layer 405 and Ru layer 401. The structure 420 shows a change in the layer 403 caused by performing an ALE etch process on the TiON layer prior to depositing the Ru. Elemental mapping of the structure 420 revealed that the ALE process removed all of the Ti and N while leaving a small amount of O remaining between the Si and Ru layers. The images demonstrate that selective ALE processes disclosed herein effectively remove TiON from underlying SiN material.

FIG. 5 shows TEM cross-section images of device structures showing the effects of an ALE process in accordance with embodiments disclosed herein. The image of structure 510 shows the results of a process of sequentially depositing Ti and Ru on SiGe without performing selective ALE, while the image of structure 520 shows the results of the same process with selective ALE performed. The structure 510 shows a well-defined TiSiGeON layer 503 formed on the SiGe base layer 505, and an Ru layer 501 formed on the TiSiGeON layer when ALE etch is not performed prior to depositing the Ru. Elemental mapping of the structure 510 by EDX confirmed substantial amounts of O between the SiGe and Ru layers. The structure 520 shows disruption of the TiSiGeON layer caused by performing an ALE etch process on the TiSiGeON layer prior to depositing the Ru. Elemental mapping of the structure 520 revealed that the ALE process removed substantially all of the O while leaving the Ti and reduced amount of N remaining between the SiGe and Ru layers. Further, the images show that the TiSiGeON layer 503 in structure 510 has a thickness of approximately 6.7 nm prior to the ALE treatment and the TiSiGeN layer 503 in structure 520 has a thickness of approximately 6.2 nm after the ALE treatment. The images demonstrate that selective ALE processes disclosed herein leave a TiSiGe layer remaining on underlying SiGe material.

Together, FIGS. 4 and 5 demonstrate that exposure of TiON and TiSiON materials to selective ALE processes disclosed herein will selectively remove TiON from an SiN layer with minimal or no damage to the profile structure of the SiN and effectively removing O and N from the TiSiON layer while preserving a TiSiN film on underlying an SiGe layer. As such, the selective ALE processes disclosed herein can selectively remove undesirable metal-containing films from a source/drain contact and sidewalls of a contact opening in an interlayer dielectric while preserving the profile of the interlayer dielectric and preserving a desirable TiSi contact film on the source/drain contact.

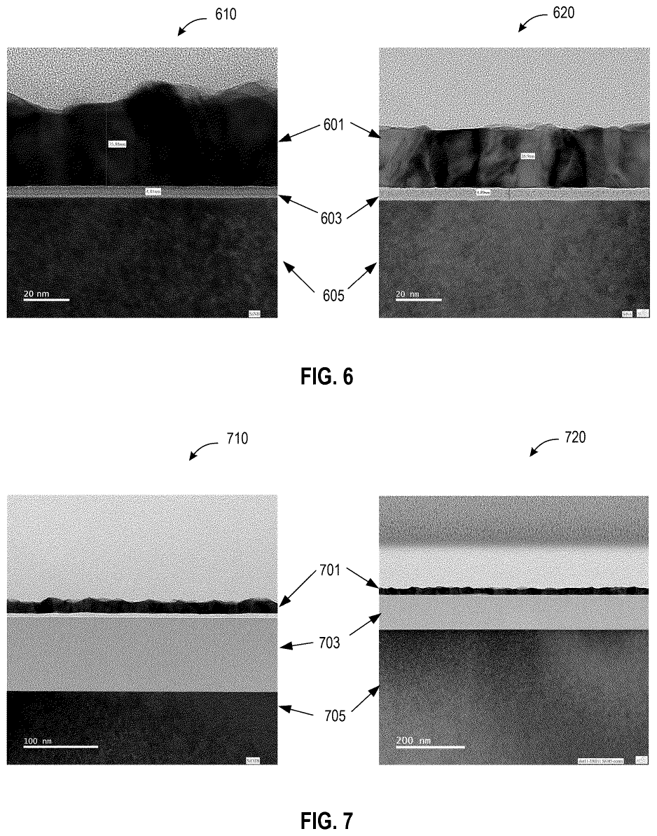

FIG. 6 shows TEM cross-section images of device structures showing the effects of an ALE process in accordance with embodiments disclosed herein. The image of structure 610 shows the results of a process of sequentially depositing SiN and Ru on Si without performing selective ALE, while the image of structure 620 shows the results of the same process with selective ALE performed. The structure 610 shows an SiN layer 603 approximately 4.81 nm thick formed on the Si layer 605, and an Ru layer 601 formed on the SiN layer 603 when ALE etch is not performed prior to depositing the Ru. The structure 620 shows an SiN layer 603 approximately 4.89 nm thick formed on the Si layer 605, and an Ru layer 601 formed thereon. The images demonstrate that selective ALE processes disclosed herein effectively preserve SiN layers with no damage to the SiN.

FIG. 7 shows TEM cross-section images of device structures showing the effects of an ALE process in accordance with embodiment disclosed herein. The image of structure 710 shows the results of a process of sequentially depositing SiO₂ and Ru on Si without performing selective ALE, while the image of structure 720 shows the results of the same process with selective ALE performed. The structure 710 shows a an SiO₂ layer 703 approximately 99.4 nm thick formed on the Si layer 705, and an Ru layer 701 formed on the SiO₂ layer 703 when ALE etch is not performed prior to depositing the Ru. The structure 720 shows an SiO₂ layer 703 approximately 99.2 nm thick formed on the Si layer 705, and an Ru layer 701 formed thereon. The images demonstrate that selective ALE processes disclosed herein effectively preserve SiO₂ layers with no damage to the SiO₂.

Together, FIGS. 6 and 7 demonstrate that exposure of SiN and SiO₂ materials typically used for interlayer dielectric will not remove the SiN or SiO₂ with minimal or no damage to the profile structure of such materials.

The present inventors have recognized that an ALE cleaning process according to embodiments disclosed herein may introduce unacceptable levels of etch residue which can potentially affect performance or reliability of the end semiconductor device. For example, the inventors confirmed that a process sequence of chemical oxide removal (COR) of native oxide from a SiGe source/drain region, deposition of Ti, exposure to ALE using F and Cl, and deposition of Ru, results in increased levels of fluorine relative to a similar process sequence without the ALE process step. While conventional wet etch, O plasma and H2O treatment processes may be used to remove the fluorine residue, these processes can cause undesirable surface oxidation. Techniques disclosed herein minimize fluorine residue on a surface while preventing or minimizing surface oxidation.

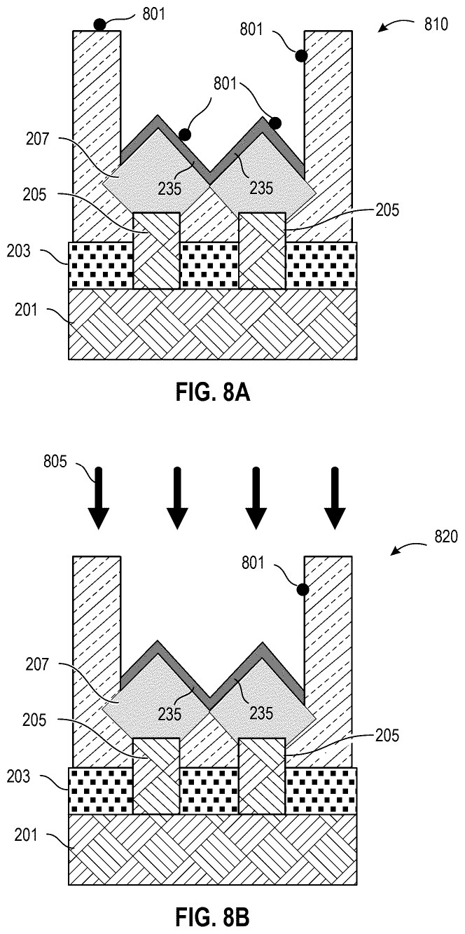

Returning to FIG. 3, the process 300 optionally includes a step 350 of performing an etch residue removal process after removing the metal-containing compound in step 315 and before the metal fill of step 320. FIGS. 8A and 8B illustrate partial cross sectional fin cuts of a semiconductor device during an etch residue removal process.

FIG. 8A shows a structure 810 after an ALE process to remove metal-containing compounds from a source/drain contact opening in an interlayer dielectric as discussed in FIGS. 2A-2D above. As shown, the process can result in etch residue 801 such as fluorine and/or chlorine compounds. While the etch residue 801 is schematically shown in particulate form, it may be a film on one or more surfaces of the structure 810.

FIG. 8B shows a substrate treatment for removing the etch residue 801. The structure 820 is exposed to the treatment schematically represented by arrows 805. As shown, the treatment 805 removes at least part of the etch residue 801 from the structure 820. The treatment 805 can include exposing the substrate to a silicon precursor gas and/or exposing the substrate to an H₂ plasma at high temperature such as 450 degrees C. That is, instead of using conventional O plasma or H₂O treatment, and Si precursor and/or H₂ plasma are introduced to remove fluorine thereby minimizing fluorine while preventing or minimizing oxidation. As used herein, the terms “precursor,” “reactant,” “reactive gas,” and the like are used interchangeably to refer to any gaseous species that can react with the substrate surface.

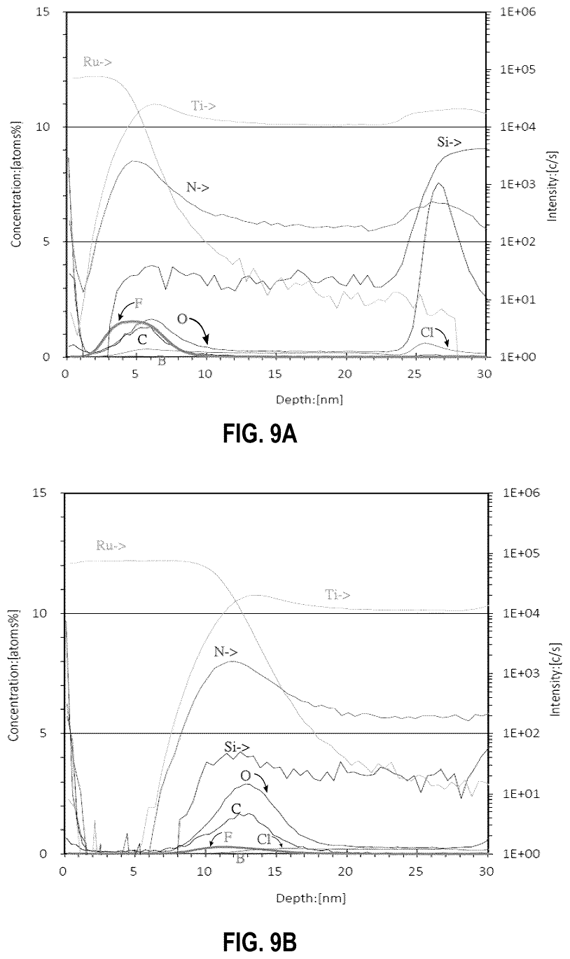

FIGS. 9A and 9B are graphs showing the effects of an etch residue removal process in accordance with embodiments of the present disclosure. FIG. 9A is a depth profile analysis of an example semiconductor structure from which TiN has been removed with an ALE process at degrees C. prior to depositing Ru, but without performing an etch residue removal process according to techniques disclosed herein. Similar depth profiles are expected for ALE processes performed at 100-400 degrees C. As shown, substantial amounts of F and Cl exist in the semiconductor structure. FIG. 9B is a depth profile analysis of a semiconductor structure similar to that of FIG. 9A, but which was exposed to an Si precursor after the ALE step and before the Ru deposition. As shown, the Si precursor treatment reduces amounts of F and Cl from the structures without substantially increasing oxygen.

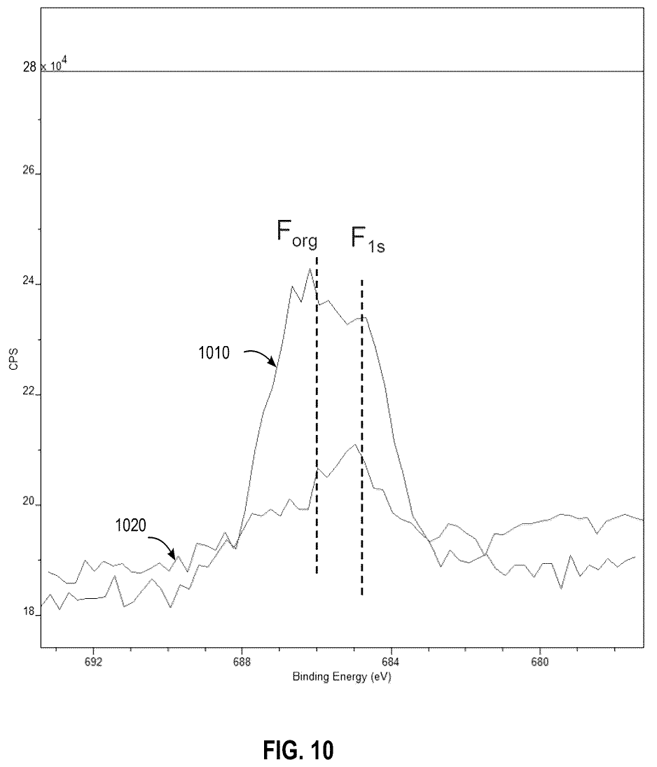

FIG. 10 is graph showing the effects of an etch residue removal process in accordance with embodiments of the present disclosure. Curve 1010 shows quantities of F in a semiconductor structure without performing an etch residue removal process according to techniques disclosed herein. Curve 1020 shows quantities of F in a semiconductor structure when performing an etch residue removal process by H₂ plasma exposure at 450 degrees C. As shown by lines F_{org} and F₁ₛ the treatment substantially reduced the amount of F in the semiconductor structure. Similar results are expected for H₂ plasma exposure at 300-600 degrees C.

Some embodiments of the present disclosure relate to methods for etching or removing metal oxides from a substrate surface. Some methods of the current disclosure utilize a fluorine-based gas and a chlorine-based gas.

Some method of this disclosure provide method which selectively remove metal oxide and metal nitride materials over other substrate material. As used in this regard, the term “selectively removing one film over another film,” and the like, refers to a first amount which is removed from a first surface or material while a second amount is removed from a second surface or material, where the second amount is less than the first amount, or no film is removed from the second surface. The term “over” used in this regard does not imply a physical orientation of one surface on top of another surface, rather a relationship of the thermodynamic or kinetic properties of the chemical reaction with one surface relative to the other surface.

One or more embodiments of the disclosure are directed to methods for the removal of metal oxides. In some embodiments, a substrate comprising an oxide surface may be treated with a fluorine-based gas and a chlorine-based gas. In some embodiments, a substrate comprising an oxide surface may be treated with a fluorine-based gas and then purged, followed by treatment with a chlorine-based gas and a subsequent purge. This cycle may be repeated to remove a predetermined thickness of metal oxide.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method, comprising:
providing a substrate comprising a silicon-containing source/drain region recessed within an interlayer dielectric opening which exposes the source/drain region;
depositing a first metal on the substrate such that the first metal reacts with the source/drain region to form a metal contact film on a surface of the source/drain region and forms a metal-containing compound comprising the first metal on a surface of the interlayer dielectric;
exposing the substrate to an atomic layer etching process to remove at least part of the metal-containing compound; and
filling the interlayer dielectric opening with a second metal.

2. The method of claim 1, wherein the depositing a first metal on the substrate comprises using a plasma deposition process to selectively deposit the first metal on the source/drain region relative to the interlayer dielectric.

3. The method of claim 1, wherein the silicon-containing source/drain region comprises at least one of SiGe and SiP.

4. The method of claim 1, wherein the interlayer dielectric region comprises at least one of SiN and SiO2.

5. The method of claim 1, wherein the first metal comprises at least one of Ti and W, and the metal contact film comprises at least one of TiSiₓ or a WSiₓ.

6. The method of claim 1, wherein the metal-containing compound is formed on a surface of the metal contact film and on a sidewall of the interlayer dielectric opening.

7. The method of claim 1, wherein the metal-containing compound comprises a metal oxide of the first metal.

8. The method of claim 7, wherein the metal oxide is at least one of TiO₂, TiON, TiSiON, and WO.

9. The method of claim 1, wherein the exposing comprises performing an atomic layer etching process using a fluorine-based gas and a chlorine-based gas.

10. The method of claim 9, wherein the atomic layer etching process comprises exposing the substrate to a plurality of cycles of alternate exposures to a fluorine-based gas and a chlorine-based gas.

11. The method of claim 9, wherein the fluorine-based gas comprises at least one of WF₆, HF and TiF₄, and the chlorine-based gas comprises at least one of BCl₃, WCl₅ and TiCl₄.

12. The method of claim 9, further comprising removing the fluorine-based gas or chlorine-based gas between exposures.

13. The method of claim 1, wherein the atomic layer etching process selectively etches the metal-containing compound relative to the metal contact film on the source/drain region and relative to the interlayer dielectric.

14. The method of claim 1, wherein:
the source/drain region comprises SiGe, the first metal comprises Ti, the metal contact film comprises TiSiₓ, and the metal-containing compound comprises TiON.

15. The method of claim 1, further comprising performing a fluorine removal process after the atomic layer etching process and before performing the metal fill.

16. The method of claim 15, wherein the fluorine removal process comprises exposing the substrate to a silicon precursor gas.

17. The method of claim 15, wherein the fluorine removal process comprises exposing the substrate to an H₂ plasma.

18. The method of claim 1, wherein the second metal is Ru.

19. A semiconductor device, comprising:
a substrate comprising a silicon-containing source/drain region recessed within an interlayer dielectric opening;
a metal contact film comprising a first metal provided on the source/drain region within the interlayer dielectric opening; and
a metal fill comprising a second metal provided on the metal contact film within the interlayer dielectric opening, wherein a first interface of the metal fill with the metal contact film at a bottom of the interlayer dielectric opening is substantially free of oxygen, and a second interface of the metal fill with the interlayer dielectric at a sidewall of the interlayer dielectric opening is substantially free of metal.

20. The semiconductor device of claim 19, wherein:
the source/drain region comprises SiGe,
the interlayer dielectric comprises SiN,
the metal contact film comprises TiSiₓ, and
the metal fill comprises Ru.
